(19) United States
(12) Patent Application Publication
(10) Pub. No.: US 2025/0040106 A1
(43) Pub. Date: Jan. 30, 2025

(54) IN-VEHICLE DEVICE

(71) Applicant: Panasonic Automotive Systems Co., Ltd., Kanagawa (JP)

(72) Inventor: Masanori YOKOTA, Kanagawa Ken (JP)

(73) Assignee: Panasonic Automotive Systems Co., Ltd., Kanagawa (JP)

(21) Appl. No.: 18/777,237

(22) Filed: Jul. 18, 2024

(30) Foreign Application Priority Data
Jul. 24, 2023 (JP) 2023-120149

(51) Int. Cl. H05K 7/20

(52) U.S. Cl. CPC H05K 7/20863; H05K 7/20154

(57) ABSTRACT

According to one embodiment, an in-vehicle electronic device (in-vehicle device) includes a case, a plate-like heat sink (heat dissipation member) that abuts on a top surface of an SoC (electronic component) to dissipate heat generated by the SoC, a cooling fin that removably abuts on an area on a top side of the heat sink including at least an area on the top surface of the SoC to promote heat dissipation of the heat sink, and a centrifugal fan (cooling fan) configured to blow cooling air along the heat sink between a plurality of fins that make up the cooling fin. The heat sink, the cooling fin, and the centrifugal fan are included inside the case.

### CROSS-REFERENCE TO RELATED APPLICATIONS

This application is based upon and claims the benefit of priority from Japanese Patent Application No. 2023-120149, filed Jul. 24, 2023, the entire contents of which are incorporated herein by reference.

### FIELD

Embodiments described herein relate generally to an in-vehicle device.

### BACKGROUND

To cool heat generated by a microprocessor, there is disclosed a cooling device in which a heat sink including a plurality of fins is provided above the microprocessor to cause wind from a blower fan to pass between the fins and thus dissipates the heat from the microprocessor (e.g., JP 2019-96766 A).

Because the fins are molded integrally in a cylindrical part that makes up the heat sink in the cooling device disclosed in JP 2019-96766 A, it was difficult to make the thickness of the fin thinner.

An object of the present disclosure is to provide an in-vehicle device that can increase moldability of cooling fins and improve productivity of a heat dissipation member.

### SUMMARY

An in-vehicle device according to an embodiment of the present disclosure includes a case; a plate-like heat dissipation member that abuts on a top surface of an electronic component, the heat dissipation member being configured to dissipate heat generated by the electronic component; a cooling fin that removably abuts on an area on a top side of the heat dissipation member including at least an area on the top surface of the electronic component, the cooling fin being configured to promote heat dissipation of the heat dissipation member; and a cooling fan configured to blow cooling air along the heat dissipation member between a plurality of fins that make up the cooling fin. The heat dissipation member, the cooling fin, and the cooling fan are included inside the case.

### BRIEF DESCRIPTION OF THE DRAWINGS

FIG. 1 is a schematic exploded perspective view illustrating an in-vehicle electronic device;

FIG. 2 is a first diagram illustrating a main structure of a heat sink;

FIG. 3 is a second diagram illustrating the main structure of the heat sink;

FIG. 4 is a diagram illustrating an example of a schematic structure of a centrifugal fan;

FIG. 5 is a first diagram illustrating a main structure of the in-vehicle electronic device;

FIG. 6 is a second diagram illustrating the main structure of the in-vehicle electronic device;

FIG. 7 is a third diagram illustrating the main structure of the in-vehicle electronic device;

FIG. 8 is a first diagram illustrating an example of a connection method between circuit boards;

FIG. 9 is a second diagram illustrating an example of the connection method between the circuit boards;

FIG. 10 is a third diagram illustrating an example of the connection method between the circuit boards;

FIG. 11 is a first diagram illustrating an example of a top surface shape of an upper chassis;

FIG. 12 is a second diagram illustrating an example of the top surface shape of the upper chassis; and

FIG. 13 is a third diagram illustrating an example of the top surface shape of the upper chassis.

### DETAILED DESCRIPTION

### Embodiment

Hereinafter, an embodiment of an in-vehicle electronic device according to the present disclosure will be described with reference to the accompanying drawings.

### Schematic Configuration of In-Vehicle Electronic Device

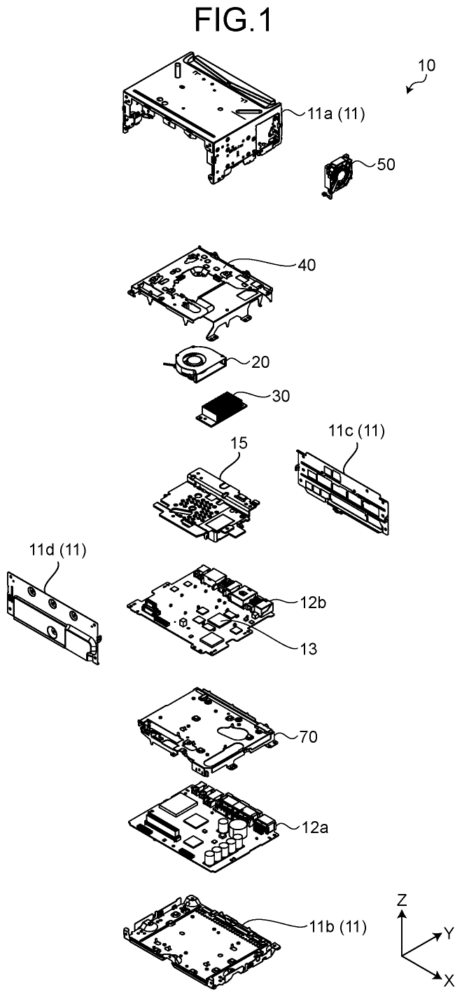

A schematic configuration of an in-vehicle electronic device 10 will be described with reference to FIG. 1. FIG. 1 is a schematic exploded perspective view illustrating the in-vehicle electronic device 10.

The in-vehicle electronic device 10 is a device that is mounted on a vehicle and performs various electronic controls such as navigation system control, audio system control, engine control, and ADAS (Advanced Driver-Assistance Systems) control. Note that the in-vehicle electronic device 10 is an example of an in-vehicle device in the present disclosure.

The in-vehicle electronic device 10 includes main components illustrated in FIG. 1.

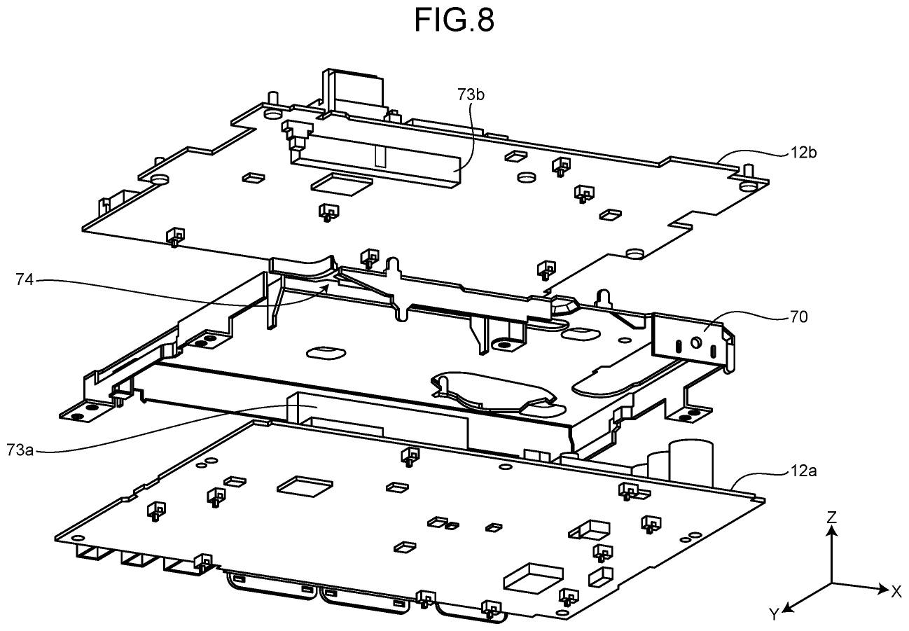

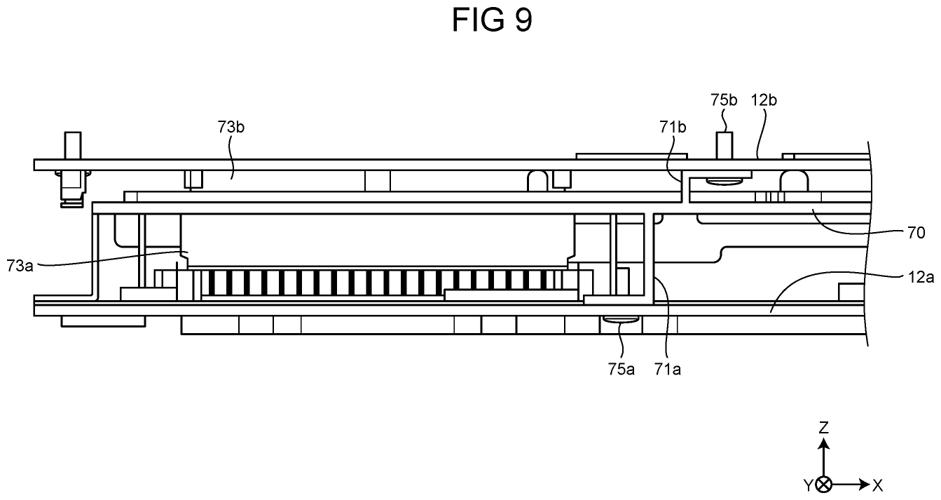

The in-vehicle electronic device 10 includes a case 11 and a plurality of circuit boards 12a and 12b enclosed in the case 11. The plurality of circuit boards 12a and 12b are stacked in a height direction (Z-axis direction in FIG. 1), and are connected to each other by board-to-board connectors (BtoB connectors). The board-to-board connectors will be described below in detail (see FIGS. 8 and 9).

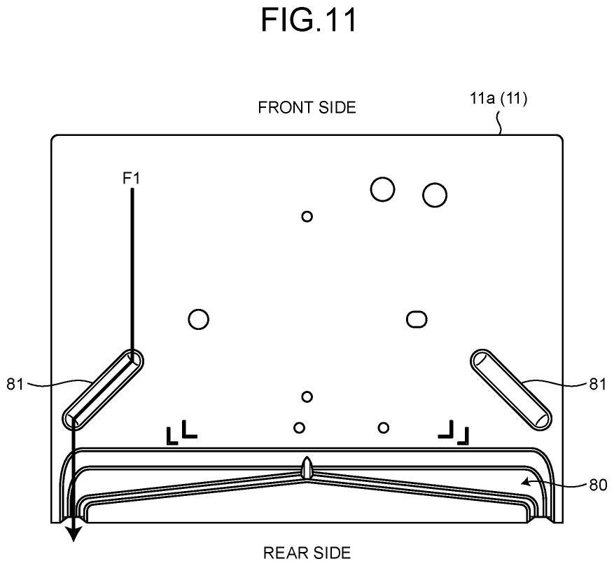

The case 11 is formed by screwing an upper chassis 11a, a lower chassis 11b, a rear chassis 11c, and a front chassis 11d to each other. Note that recesses letting drops of water escape are formed on a top surface of the upper chassis 11a to prevent water from entering the inside of the case 11 by dew condensation inside the vehicle. Details will be described below (see FIGS. 11, 12, and 13).

An SoC (System on a Chip) 13 is mounted on the circuit board 12b. The SoC 13 is made by implement many or all of functions required for operations of the system on one semiconductor chip. For example, the SoC 13 includes a processor function such as CPU and GPU, a memory function, a communication interface function, and the like. The SoC 13 has a merit that an electronic device can be made smaller, lighter, and faster, but it is necessary to perform cooling on the SoC because the SoC generates a lot of heat during operations. Note that the SoC 13 is an example of an electronic component in the present disclosure.

A bracket 70 is mounted between the circuit board 12a and the circuit board 12b. The bracket 70 is fastened to the circuit board 12a and is also fastened to the circuit board 12b. This results in suppressing vibration of the circuit board 12a and the circuit board 12b caused by the travel of the vehicle, for example. Moreover, the bracket 70 provides conduction between ground lines of the circuit board 12a and the circuit board 12b to adjust ground potential between different circuit boards.

A heat sink 15 is installed on the upper side (Z-axis positive side) of the circuit board 12b to abut on the SoC 13. The heat sink 15 is molded from an aluminum plate with high thermal conductivity, for example, to dissipate heat generated by the SoC 13 to the inside of the case 11.

A cooling fin 30 is removably installed on the upper side of the SoC 13 while interposing the heat sink 15 therebetween. The cooling fin 30 includes a plurality of fins along the X-axis. Because the cooling fin 30 can be removed, the in-vehicle electronic device 10 in which a heat quantity of the SoC 13 is small can perform required heat dissipation by only the heat sink 15 without attaching the cooling fin 30. The cooling fin 30 is manufactured by performing extrusion on aluminum, for example.

A centrifugal fan 20 is installed on the X-axis negative side of the cooling fin 30. The cooling fin 30 breathes in air inside the case 11 from the Z-axis positive side and blows it out toward the plurality of fins included in the cooling fin 30. The flow of the blown air passes between the plurality of fins included in the cooling fin 30 to take away the heat generated by the SoC 13. In other words, the flow of the air blown out by the centrifugal fan 20 acts as cooling air. Note that the centrifugal fan 20 is an example of a cooling fan in the present disclosure.

A bracket 40 is installed on the upper side (Z-axis positive side) of the cooling fin 30 so as to cover the tip side of the cooling fin 30. The bracket 40 causes the cooling air blown out by the centrifugal fan 20 to pass between the plurality of fins included in the cooling fin 30 and guide it to an axial-flow fan 50 to be described later. Note that the bracket 40 is an example of an air guide member in the present disclosure.

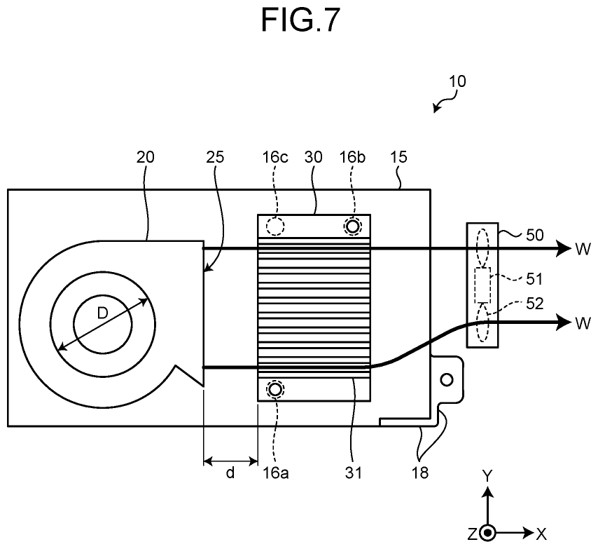

The axial-flow fan 50 is installed on the side surface of the upper chassis 11a on the X-axis positive side. The axial-flow fan 50 discharges the cooling air passing through the cooling fin 30 to the outside of the case 11. Note that the axial-flow fan 50 is an example of an exhaust fan in the present disclosure. An air guide path from the centrifugal fan 20 to the axial-flow fan 50 will be described below in detail (see FIG. 7).

### Main Structure of Heat Sink

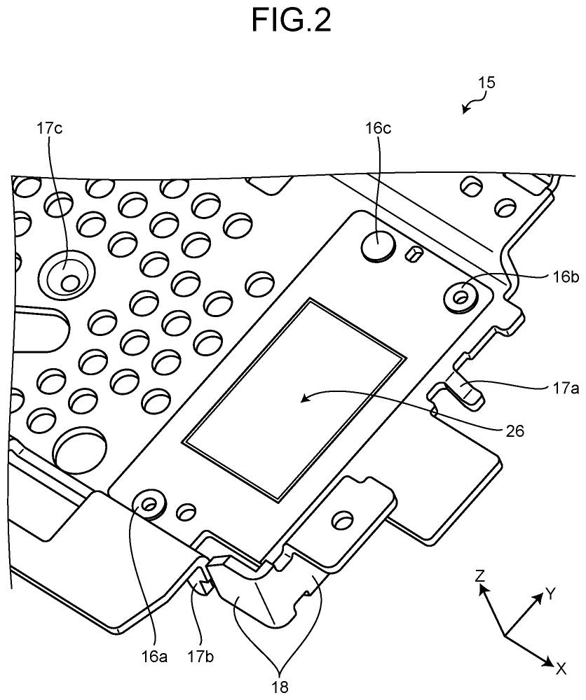

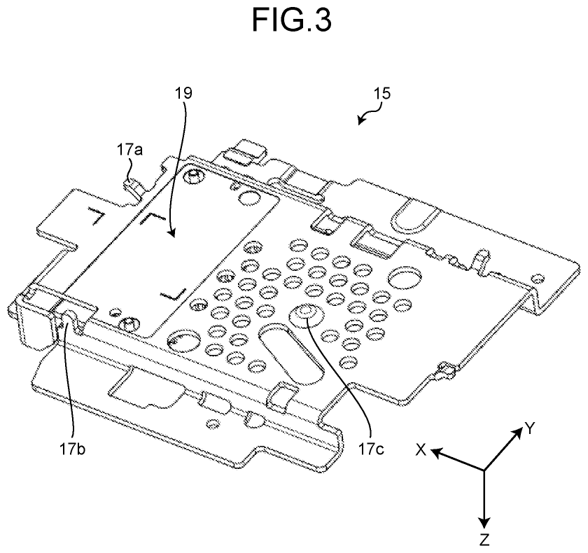

A main structure of the heat sink 15 will be described with reference to FIGS. 2 and 3. FIG. 2 is a first diagram illustrating a main structure of the heat sink. FIG. 3 is a second diagram illustrating the main structure of the heat sink.

FIG. 2 illustrates a structure of a portion in the heat sink 15 that abuts on the bottom surface of the cooling fin 30. In the heat sink 15, a planar area 26 is formed on the back side of a planar proximity area 19 (see FIG. 3) that abuts on the top surface of the SoC 13. Moreover, a protrusion 16a, a protrusion 16b, and a protrusion 16c protruding to the Z-axis positive side are formed around the planar area 26 to surround the planar area 26. The protrusion 16a, the protrusion 16b, and the protrusion 16c are formed so that their protrusion amounts from the planar area 26 become equal.

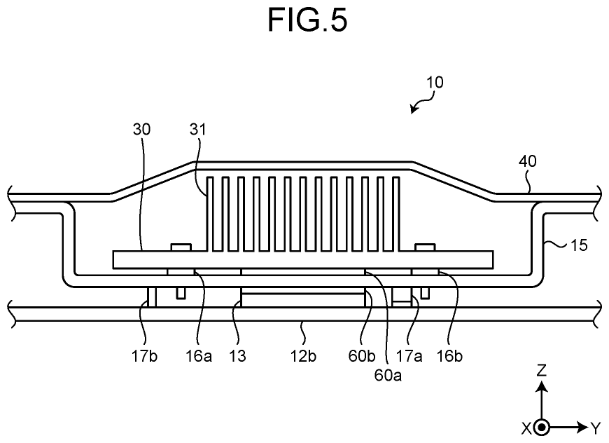

The protrusion 16a, the protrusion 16b, and the protrusion 16c form a minute gap between the top surface of the heat sink 15 and the bottom surface of the cooling fin 30 by abutting on the bottom surface of the cooling fin 30 when the cooling fin 30 is attached to the upper side (Z-axis positive side) of the heat sink 15. A GAP filler 60a to be described later is filled into the minute gap. The GAP filler 60a will be described below in detail (see FIG. 5).

Note that screw holes when the heat sink 15 and the cooling fin 30 are screwed are formed in at least two protrusions that sandwich the planar area 26 among the protrusion 16a, the protrusion 16b, and the protrusion 16c. In FIG. 2, screw holes are formed in the protrusion 16a and the protrusion 16b.

An abutment 17a and an abutment 17b bent to the Z-axis negative side are formed on the end of the heat sink 15. Moreover, an abutment 17c protruding toward the Z-axis negative side is formed in the heat sink 15. The abutment 17a, the abutment 17b, and the abutment 17c are formed around the planar area 26 to surround the planar area 26. Moreover, the abutment 17a, the abutment 17b, and the abutment 17c are formed so that their protrusion amounts from the bottom surface of the heat sink 15 become equal.

The abutment 17a, the abutment 17b, and the abutment 17c abut on the top surface of the circuit board 12b when the heat sink 15 is attached to the circuit board 12b. Moreover, a minute gap is formed between the bottom surface of the heat sink 15 and the top surface of the SoC 13 installed in the circuit board 12b. A GAP filler 60b to be described later is filled into the minute gap. The GAP filler 60b will be described below in detail (see FIG. 5).

Moreover, a wall 18 made by bending the end of the heat sink 15 to the top side (Z-axis positive side) is formed on the corner of the heat sink 15 on the X-axis positive side. The wall 18 controls the flow of cooling air passing through the cooling fin 30. The action of the wall 18 will be described below in detail (see FIG. 7).

FIG. 3 illustrates a structure of a portion in the heat sink 15 that is close to the top surface of the SoC 13. In other words, FIG. 3 is a diagram obtained by viewing FIG. 2 from the back side (Z-axis negative side).

The circuit board 12b is installed on the back side of the heat sink 15 as illustrated in FIG. 1. Moreover, the top surface of the SoC 13 mounted on the circuit board 12b is arranged in a state where the top surface is close to the proximity area 19 illustrated in FIG. 3.

The abutment 17a, the abutment 17b, and the abutment 17c formed on the back side of the heat sink 15 abut on the top surface of the circuit board 12b as described above. Moreover, a minute gap is formed between “the top surface of the SoC 13 installed in the circuit board 12b” and “the bottom surface of the heat sink 15, that is, the proximity area 19”. The GAP filler 60b to be described later is filled into the minute gap. The GAP filler 60b will be described below in detail (see FIG. 5).

### Schematic Structure of Centrifugal Fan

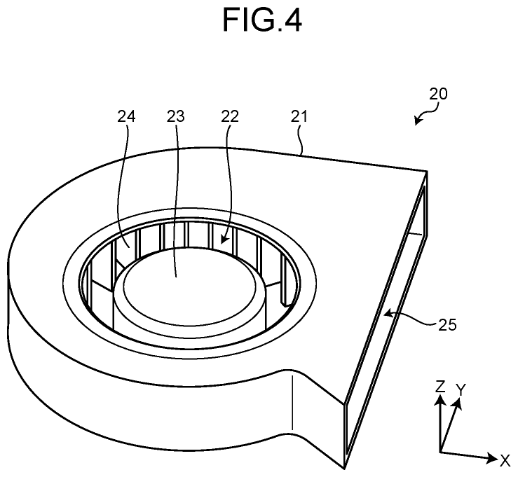

A schematic structure of the centrifugal fan 20 will be described with reference to FIG. 4. FIG. 4 is a diagram illustrating an example of a schematic structure of the centrifugal fan.

The centrifugal fan 20 has a configuration that a motor 23 and a blade 24 are built into a housing 21. The blade 24 is rotatably driven on the XY plane by a rotational driving force of the motor 23.

An intake port 22 and a blower port 25 are formed in the housing 21. The intake port 22 takes air inside the case 11 into the housing 21 by the rotation of the blade 24. The blower port 25 blows the air taken in from the intake port 22 toward the X-axis positive side. The air blown from the blower port 25 acts as cooling air that cools the cooling fin 30.

### Main Structure of In-Vehicle Electronic Device

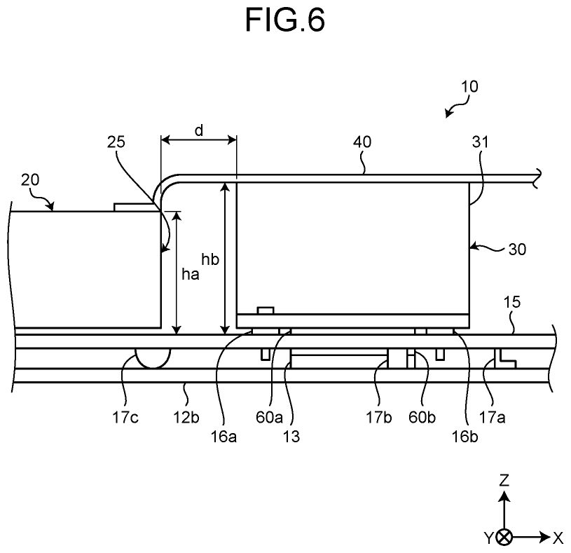

A main structure of the in-vehicle electronic device 10 will be described with reference to FIGS. 5, 6, and 7. FIG. 5 is a first diagram illustrating a main structure of the in-vehicle electronic device. FIG. 6 is a second diagram illustrating the main structure of the in-vehicle electronic device. FIG. 7 is a third diagram illustrating the main structure of the in-vehicle electronic device.

FIG. 5 illustrates a schematic structure of the YZ cross section of the in-vehicle electronic device 10 cut at a position including the SoC 13.

A space between the heat sink 15 and the top surface of the SoC 13 mounted on the circuit board 12b is filled up with the GAP filler 60b. The GAP filler 60b has thermal conductivity, and makes heat generated from the SoC 13 be conducted to dissipate the heat to the heat sink 15. Note that the GAP filler 60b is an example of a resin member in the present disclosure.

Because the space is formed between the top surface of the SoC 13 and the bottom surface of the heat sink 15 by the abutment 17a and the abutment 17b formed on the heat sink 15, the GAP filler 60b is filled up uniformly.

The cooling fin 30 is removably attached onto the top side of the heat sink 15. Specifically, the cooling fin 30 is screwed at the protrusion 16a and the protrusion 16b formed on the heat sink 15. Because the protrusion 16a and the protrusion 16b have an equal protrusion amount, a space is formed between the top surface of the heat sink 15 and the bottom surface of the cooling fin 30. This space is filled up with the GAP filler 60a over a range in which the SoC 13 is mounted. The GAP filler 60a has thermal conductivity similar to the GAP filler 60b described above. The GAP filler 60b makes heat of the heat sink 15 be conducted to the cooling fin 30 to promote cooling of the heat sink 15.

The cooling fin 30 includes a plurality of fins 31 that stand up at a regular interval parallel to each other along the XZ plane. The bracket 40 is installed on the upper side of the heat sink 15 so as to cover the tip side of the fins 31. Note that a minute gap is provided between the tip of the fins 31 and the bracket 40.

The cooling air blown by the centrifugal fan 20 described above flows between the plurality of fins 31 from the negative side of the X-axis to the positive side of the X-axis. At this time, an exhaust duct is formed because the tip side of the fins 31 is covered by the bracket 40. Note that, because a minute gap exists between the tip side of the fins 31 and the bracket 40 as described above but the bracket 40 is attached firmly to the heat sink 15, an exhaust duct structure is secured. As a result, because the cooling air from the centrifugal fan 20 is efficiently guided to the space between the fins 31 and the space in which the cooling air flows is limited, the flow velocity of the cooling air is improved. For that reason, the cooling of the fin 31 is promoted. Moreover, because the heat sink 15 is attached firmly to the bracket 40 and heat conduction from the heat sink 15 to the bracket 40 occurs, the cooling effect of the heat sink 15 can be also expected.

FIG. 6 illustrates a schematic structure of the XZ cross section of the in-vehicle electronic device 10 cut at a position including the SoC 13 and the centrifugal fan 20.

A space between the top surface of the circuit board 12b and the bottom surface of the heat sink 15 is supported by the above abutments 17a and 17b as well as the abutment 17c. Therefore, even if a warpage occurs on the circuit board 12b, a uniform space to be filled with the GAP filler 60b is formed on the upper side of the SoC 13 between the SoC 13 and the heat sink 15.

Moreover, the bracket 40 described above extends up to a position on the top surface of the centrifugal fan 20. Therefore, the cooling air blown from the centrifugal fan 20 advances toward the X-axis positive side inside an area surrounded by the bracket 40 and the heat sink 15. As described above, because the cooling air can be guided along the top surface of the heat sink 15 and between the plurality of fins 31 included in the cooling fin 30 by forming an air guiding duct that limits an air guiding range of the cooling air, cooling efficiency is improved. Moreover, because no more cooling air leaks, it is possible to reduce an air blowing sound generated by the operation of the centrifugal fan 20.

Note that a height hb of the fin 31 included in the cooling fin 30 is configured to be higher than a height ha of the blower port 25 of the centrifugal fan 20. By employing such a configuration, it is possible to reduce ventilation resistance of the cooling air blown from the blower port 25. For example, if the height hb of the fin 31 is configured to be lower than the height ha of the blower port 25 of the centrifugal fan 20 to cover the top surface of the centrifugal fan 20 and the tip of the fin 31 by the bracket 40, an air guiding range of the cooling air blown from the blower port 25 becomes narrow. In this case, because ventilation resistance occurs by narrowing the air guiding range, cooling efficiency may decrease.

FIG. 7 is a diagram of the in-vehicle electronic device 10 viewed from directly above the centrifugal fan 20 and the cooling fin 30.

Cooling air W blown from the blower port 25 of the centrifugal fan 20 advances to the X-axis positive side along the top surface of the heat sink 15 to pass between the fins 31 of the cooling fin 30. Note that the bottom surface of the cooling fin 30 is screwed to the heat sink 15 at positions of the protrusion 16a and the protrusion 16b in a state where the bottom abuts on the protrusions 16a, 16b, and 16c formed on the top surface of the heat sink 15.

The cooling air W passing between the fins 31 of the cooling fin 30 is discharged to the outside of the case 11 by the rotation of the axial-flow fan 50 attached to the upper chassis 11a (see FIG. 1) that makes up the case 11.

At this time, it is desirable that a distance d between the blower port 25 of the centrifugal fan 20 and the fin 31 of the cooling fin 30 is not less than the half of a blade diameter D that is a diameter of the blade 24 of the centrifugal fan 20 (see FIG. 4), in other words, “d≥D/2”. This reason is that the cooling air W blown from the blower port 25 of the centrifugal fan 20 requires a certain level of distance until a traveling direction is stabilized.

The axial-flow fan 50 includes a fan 52 rotationally driven by a motor 51 inside an outer frame member whose suction side of the cooling air W and discharge side of the cooling air W are opened. The axial-flow fan 50 sucks the cooling air W passing between the fins 31 of the cooling fin 30 by the rotation of the fan 52, and emits the cooling air to the outside of the case 11.

To increase cooling efficiency, it is desirable that the blower port 25 of the centrifugal fan 20, the fins 31 of the cooling fin 30, and the axial-flow fan 50 are arranged on a straight line. However, depending on the structure of the circuit board 12b, the installation state of input-output terminals etc. to be attached to the inside of the case 11, and the like, a desirable arrangement may not be realized. For example, in the case of FIG. 7, the center of the blower port 25 of the centrifugal fan 20 aligns with the center of the fin 31 of the cooling fin 30, but the central axis of the axial-flow fan 50 is offset to the Y-axis positive side. For that reason, in the example of FIG. 7, the wall 18 is formed on the ends of the X-axis positive side and the Y-axis negative side of the heat sink 15 to control the flow of the cooling air W. Specifically, the cooling air W flowing on the Y-axis negative side passes between the fins 31 of the cooling fin 30 and then hits the wall 18 to change the traveling direction to the Y-axis positive side. Thus, the leak of the cooling air W can be reduced, and the cooling air W can be guided to the axial-flow fan 50 without leaking the cooling air. Note that the installation position and shape of the wall 18 are designed as appropriate in accordance with the structure of the circuit board 12b, the installation state of input-output terminals etc. to be attached to the inside of the case 11, and the like.

### Connection Structure Between Circuit Boards

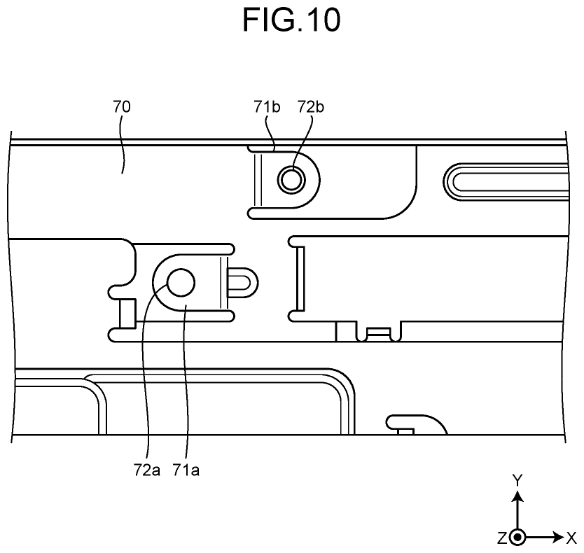

A connection structure between the circuit board 12a and the circuit board 12b will be described with reference to FIGS. 8, 9, and 10. FIG. 8 is the first diagram illustrating an example of the connection method between the circuit boards. FIG. 9 is the second diagram illustrating an example of the connection method between the circuit boards. FIG. 10 is the third diagram illustrating an example of the connection method between the circuit boards.

A board-to-board connector 73a provided on the circuit board 12a and a board-to-board connector 73b provided on the circuit board 12b are connected while interposing a connector passage part 74 formed on the bracket 70 therebetween.

In the in-vehicle electronic device 10 according to the present embodiment, the board-to-board connectors 73a and 73b include many connection pins such as 200 pins, for example. For that reason, to facilitate insertion and removal of the board-to-board connectors 73a and 73b during maintenance etc., it is desirable to lower a contact load according to the connection part of the connectors. In the in-vehicle electronic device 10 according to the present embodiment, by making a contact point between the board-to-board connectors 73a and 73b be a single contact point, it is easy to insert and remove the board-to-board connectors 73a and 73b.

In this regard, however, by lowering a contact load according to the connection part of the board-to-board connectors 73a and 73b, slight sliding occurs at the contact point of the board-to-board connectors 73a and 73b due to the vibration etc. of the vehicle equipped with the in-vehicle electronic device 10, and the abrasion of the contact point may occur by the slight sliding.

For that reason, in the in-vehicle electronic device 10 according to the present embodiment, as illustrated in FIG. 9, an arm 71a and an arm 71b of the bracket 70 formed near the board-to-board connectors 73a and 73b are respectively fastened with the circuit boards 12a and 12b to prevent a variation of a distance between the circuit board 12a and the circuit board 12b due to the vibration of the vehicle.

More specifically, as illustrated in FIGS. 9 and 10, the arm 71a is formed near the board-to-board connectors 73a and 73b of the bracket 70 by cutting out a portion of the bracket 70 and bending it toward the circuit board 12a. Moreover, the arm 71b is formed near the board-to-board connectors 73a and 73b of the bracket 70 by cutting out a portion of the bracket 70 and bending it toward the circuit board 12b.

The tip of the arm 71a is bent in a direction along the circuit board 12a, and a screw hole 72a is opened from the tip. The circuit board 12a and the arm 71a are fastened by a screw 75a inserted into the screw hole 72a.

The tip of the arm 71b is bent in a direction along the circuit board 12b, and a screw hole 72b is opened from the tip. The circuit board 12b and the arm 71b are fastened by a screw 75b inserted into the screw hole 72b.

Because a variation of the distance between the circuit board 12a and the circuit board 12b due to the vibration of the vehicle is prevented by employing such the fastening structure between the circuit boards, the occurrence of slight sliding at the contact point of the board-to-board connectors 73a and 73b is suppressed.

### Top Surface Structure of Case

The top surface structure of the case 11 will be described with reference to FIG. 11. FIG. 11 is the first diagram illustrating an example of the top surface shape of the upper chassis.

A drain 80 and recesses 81 are formed in the upper chassis 11a that makes up a portion of the case 11 of the in-vehicle electronic device 10.

The drain 80 is a recessed groove that is formed along the width direction of the upper chassis 11a and of which width-direction both ends are bent toward the rear side of the upper chassis 11a. Typically, the case 11 is installed in the vehicle in a state where the case is inclined so that the front side is located at a position higher than the rear side. Therefore, when drops of water are generated inside the vehicle, the generated drops of water fall on the surface of the upper chassis 11a and then slide down from the front side to the rear side of the upper chassis 11a. The drain 80 catches the drops of water sliding down the upper chassis 11a and drains them from the width-direction both ends of the upper chassis 11a to the lower side of the case 11. As described above, by forming the drain 80, it is possible to prevent various connection connectors exposing from the rear chassis 11c from being exposed to the drops of water sliding down the surface of the upper chassis 11a.

The recesses 81 are grooves of which the rear sides of the upper chassis 11a are located closer to the width-direction both ends of the upper chassis 11a than the front sides of the upper chassis 11a. The recesses 81 catch the drops of water sliding down the surface of the upper chassis 11a and flow the drops of water toward the width-direction both ends of the upper chassis 11a.

The drops of water, which pass through the rear end of each of the recesses 81, flow down in a corresponding portion of the drain 80 bent toward the rear side of the upper chassis 11a and then are drained to the lower side of the case 11. In other words, the drops of water are drained along a drainage route F1. As described above, the drops of water can be guided onto the width-direction both ends of the upper chassis 11a in an earlier step by providing the recesses 81. As a result, various connection connectors exposing from the rear chassis 11c can be more surely prevented from being exposed to water.

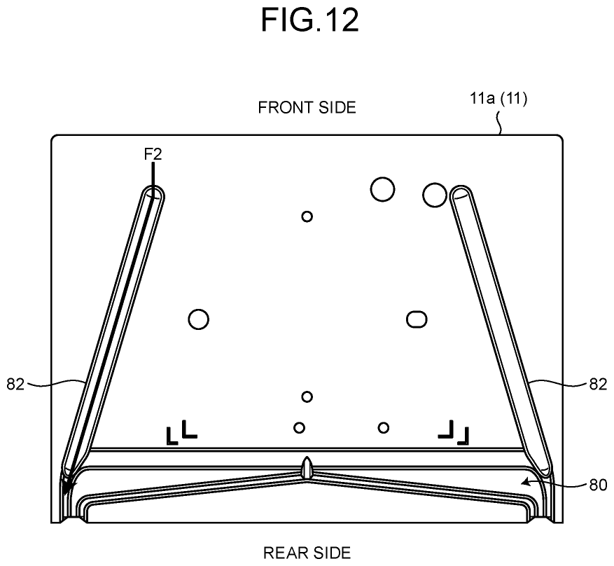

Next, the first modification example of the drainage structure of the drops of water will be described with reference to FIG. 12. FIG. 12 is the second diagram illustrating an example of the top surface shape of the upper chassis.

Instead of the recesses 81 described above, recesses 82 are formed in the upper chassis 11a illustrated in FIG. 12. Each of the recesses 82 is formed by reducing an angle between the recess 81 and a corresponding end of the left and right ends of the upper chassis 11a and lengthening the length of the recess 81. Furthermore, the rear side of each of the recesses 82 in the upper chassis 11a is connected to the drain 80.

In FIG. 12, the drops of water are drained along a drainage route F2. As described above, the flow of the drops of water caught in the recesses 82 can be quickened by forming the recesses 82. Moreover, because each of the recesses 82 is connected to the drain 80, the drops of water flowing down the recesses 82 can be immediately drained. As a result, it is possible to still more improve a water exposing prevention effect of various connection connectors exposing from the rear chassis 11c.

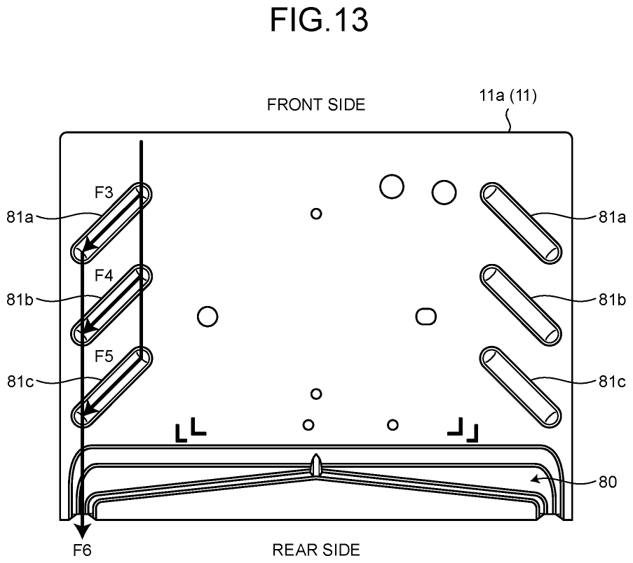

Next, the second modification example of the drainage structure of the drops of water will be described with reference to FIG. 13. FIG. 13 is the third diagram illustrating an example of the top surface shape of the upper chassis.

In the upper chassis 11a illustrated in FIG. 13, a plurality of recesses 81a, 81b, and 81c having the same shape as that of the recess 81 described above are formed on the left-right both ends of the upper chassis 11a.

In FIG. 13, the drops of water caught in the recess 81a are drained along a drainage route F3. Moreover, the drops of water caught in the recess 81b are drained along a drainage route F4. Moreover, the drops of water caught in the recess 81c are drained along a drainage route F5. As described above, by forming the plurality of recesses 81a, 81b, and 81c, because a probability of catching the drops of water increases compared to the case where the one recess 81 illustrated in FIG. 11 is formed, it is possible to still more improve a water exposing prevention effect of various connection connectors exposing from the rear chassis 11c.

### Effects of Present Embodiment

As described above, the in-vehicle electronic device 10 (in-vehicle device) according to the present embodiment includes: the case 11; the plate-like heat sink 15 (heat dissipation member) that abuts on the top surface of the SoC 13 (electronic component) and is configured to dissipate heat generated by the SoC 13; the cooling fin 30 that removably abuts on an area on the top side of the heat sink 15 including at least an area of the top surface of the SoC 13 and is configured to promote heat dissipation of the heat sink 15; and the centrifugal fan 20 (cooling fan) configured to blow cooling air along the heat sink 15 between the plurality of fins 31 that make up the cooling fin 30, in which the heat sink 15, the cooling fin 30, and the centrifugal fan 20 are included inside the case 11. Therefore, because the cooling fin 30 can be manufactured separately from the heat sink 15, it is possible to increase moldability of the cooling fin 30 and to improve productivity of the heat sink 15. Moreover, because the cooling fin 30 and the heat sink 15 can be separated, the presence or absence of the cooling fin 30 can be selected in accordance with the heat dissipation amount of the SoC 13. As a result, the heat sink 15 can be reused between the plurality of different in-vehicle electronic devices 10.

Moreover, the in-vehicle electronic device 10 (in-vehicle device) according to the present embodiment further includes: the bracket 40 (air guide member) that is installed so as to cover the blower port 25 of the centrifugal fan 20 (cooling fan) and the tip side of the fin 31 to guide the cooling air W blown by the centrifugal fan 20 between the plurality of fins 31 included in the cooling fin 30; and the axial-flow fan 50 (exhaust fan) configured to discharge the cooling air W passing through the cooling fin 30 to the outside of the case 11. Therefore, because the bracket 40 acts as an exhaust duct, heat dissipation by the cooling fin 30 can be promoted.

Moreover, in the in-vehicle electronic device 10 (in-vehicle device) according to the present embodiment, the height hb from the top surface of the heat sink 15 (heat dissipation member) to the tip of the cooling fin 30 is higher than the height ha of the blower port 25 of the centrifugal fan 20 (cooling fan). Therefore, the cooling air from the centrifugal fan 20 can efficiently hit the fin 31.

Moreover, in the in-vehicle electronic device 10 (in-vehicle device) according to the present embodiment, the GAP fillers 60a and 60b (resin members) having thermal conductivity are filled up between the top surface of the heat sink 15 and the bottom surface of the cooling fin 30 and between the top surface of the SoC 13 (electronic component) and the bottom surface of the heat sink 15 (heat dissipation member). Therefore, heat dissipation of the SoC 13 can be promoted.

Moreover, in the in-vehicle electronic device 10 (in-vehicle device) according to the present embodiment, the heat sink 15 (heat dissipation member) is installed to have gaps between the top surface of the heat sink 15 and the bottom surface of the cooling fin 30 and between the top surface of the SoC 13 (electronic component) and the bottom surface of the heat sink 15 to fill with the GAP fillers 60a and 60b (resin members). Therefore, independently of a surface state of each member and a warpage state of each member, the gaps filling with the GAP fillers 60a and 60b can be formed between the members. As a result, heat dissipation of the SoC 13 can be promoted.

According to the in-vehicle device of the present disclosure, it is possible to increase moldability of the cooling fins and improve productivity of the heat dissipation member.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An in-vehicle device comprising:
a case;
a plate-like heat dissipation member that abuts on a top surface of an electronic component, the heat dissipation member being configured to dissipate heat generated by the electronic component;
a cooling fin that removably abuts on an area on a top side of the heat dissipation member including at least an area on the top surface of the electronic component, the cooling fin being configured to promote heat dissipation of the heat dissipation member; and
a cooling fan configured to blow cooling air along the heat dissipation member between a plurality of fins that make up the cooling fin, the heat dissipation member, the cooling fin, and the cooling fan being included inside the case.

2. The in-vehicle device according to claim 1, further comprising:
an air guide member that is installed to cover a blower port of the cooling fan and a tip side of the fin, the air guide member being configured to guide the cooling air blown by the cooling fan between the plurality of fins included in the cooling fin; and
an exhaust fan configured to discharge the cooling air passing through the cooling fin to an outside of the case.

3. The in-vehicle device according to claim 1, wherein
a height from a top surface of the heat dissipation member to a tip of the cooling fin is higher than a height of a blower port of the cooling fan.

4. The in-vehicle device according to claim 2, wherein
a height from a top surface of the heat dissipation member to a tip of the cooling fin is higher than a height of a blower port of the cooling fan.

5. The in-vehicle device according to claim 1, wherein
resin members having thermal conductivity are filled up between the top surface of the electronic component and a bottom surface of the heat dissipation member and between a top surface of the heat dissipation member and a bottom surface of the cooling fin.

6. The in-vehicle device according to claim 2, wherein
resin members having thermal conductivity are filled up between the top surface of the electronic component and a bottom surface of the heat dissipation member and between a top surface of the heat dissipation member and a bottom surface of the cooling fin.

7. The in-vehicle device according to claim 5, wherein
the heat dissipation member is installed to have gaps between the top surface of the electronic component and the bottom surface of the heat dissipation member and between the top surface of the heat dissipation member and the bottom surface of the cooling fin to fill with the resin members.

8. The in-vehicle device according to claim 6, wherein
the heat dissipation member is installed to have gaps between the top surface of the electronic component and the bottom surface of the heat dissipation member and between the top surface of the heat dissipation member and the bottom surface of the cooling fin to fill with the resin members.
